(19) United States
(12) Patent Application Publication
(10) Pub. No.: US 2025/0080111 A1
(43) Pub. Date: Mar. 6, 2025

(54) LOW ON-RESISTANCE HIGH POWER SWITCH

(71) Applicant: Visic Technologies Ltd., Ness Ziona (IL)

(72) Inventors: Lev Stessin, Rehovot (IL); Gregory Bunin, Tel Aviv (IL); Guillermo Romero, Phoenix, AZ (US); Valery Veprinsky, Ness Ziona (IL); Yulia Roiter, Ashdod (IL)

(21) Appl. No.: 18/457,362

(22) Filed: Aug. 29, 2023

(51) Int. Cl. H03K 17/687; H01L 23/528; H01L 27/088

(52) U.S. Cl. CPC H03K 17/6871; H01L 23/528; H10D 84/83

(57) ABSTRACT

An electrical power switch, the power switch comprising: an array of rows and columns of lateral field effect (LFET) transistors, each transistor having a source, drain, and gate; a plurality of internal interconnect layers comprising metallizations configured to connect the transistors to operate in parallel; a source electrode and a drain electrode for respectively connecting the sources and drains of the transistors to an external circuit; and a bridging interconnect layer comprising: a plurality of undulating source bridging conductors that provide electrical connections for the sources of the transistors to the source electrode; and a plurality of undulating drain bridging conductors that provide electrical connections for the drains of the transistors to the drain electrode.

### FIELD

Embodiments of the invention relate to a high voltage, high power switch comprising a low resistance redistribution layer (RDL).

### BACKGROUND

Modern optical and electronic devices of almost all types, from computers to powertrains, comprise power switching circuitry for generating timing pulses, data packets, and/or delivering power. For delivering power to an electric powertrain, such as a powertrain that powers an electric vehicle, power switches are required that can carry large currents, be turned ON and OFF rapidly to couple and decouple a high voltage electric power source to the power train, and when ON have relatively low on-resistance.

For example, a high voltage power inverter operated to deliver AC power to an automotive traction motor from a DC power source may comprise a half bridge having a high side switch, a low side switch, and a PCB control circuit to control the switches that invert the DC power to AC power. To provide the high currents and voltages that the power inverter is required to deliver, the high and low side switches may be lateral field effect transistor (LFET) switches, each switch comprising an array of a relatively large number of LFET transistors. The LFETs are electrically connected to operate in parallel to support the high currents and voltages by an intricate, layered network of conductors, referred to as a redistribution layer (RDL). The RDL comprises relatively long conductive interconnects in different layers of the RDL that overlay and connect to sources, drains, and/or gates of the LFET transistors, and vias that connect interconnects in different layers.

For efficient operation of the high power inverter and for the inverter to have low on-resistance it is advantageous that the high and low side switches have low drain-source resistances when ON (RDS(on)), that the RDL interconnects be appropriately insulated from each other, and that the RDL have low resistance. However, configuring interconnects and vias that connect the interconnects that are appropriately insulated to provide an RDL having relatively low resistance is a complex task. The complexity increases as the number of LFETs advantageous for supporting large currents and voltages increases.

### SUMMARY

An aspect of an embodiment of the disclosure relates to providing a high voltage, high power LFET switch comprising an array of a large number of LFET transistors and a relatively low resistance RDL. The RDL comprises a bridging interconnect layer and a plurality of, optionally three, internal interconnect layers having metallization layers that connect together features of the transistors. The bridging interconnect layer comprises relatively low resistance undulating ribbon and/or wire bond conductors, generically referred to as bridging conductors, that connect the internal interconnect layers to external electrodes that may be used to connect the LFET power switch and array of LFET transistor to external circuits. Metallization layers in different layers of the relatively small number of internal interconnect layers are connected by conductive plugs that fill a plurality of vias formed in insulation layers separating the interconnect layers. The metallization layers and conductive plugs deliver currents from the bridging conductors to the LFET transistors and return current from the LFET transistors to the bridging conductors along relatively short and low resistance conductive paths perpendicular to the internal metallization layer. The short conductive paths contribute to reducing resistance of the RDL.

In an embodiment the plurality of internal interconnect layers comprises first, second, and third interconnect layers. The first interconnect layer, also referred to as a gate interconnect layer, electrically connects together the gates of a plurality, and optionally all the LFET transistors. The second interconnect layer comprises first and second metallization regions, optionally referred to as source and drain metallization layers, respectively having source and drain conducting tines that overlay the LFET transistors. The source conducting tines interleave with the drain conducting tines and electrically connect together the sources of a plurality, and optionally all of the LFET transistors. The drain conducting tines electrically connect together the drains of a plurality, and optionally all of the LFET transistors. A third interconnect layer, optionally referred to as a band interconnect layer comprises source metallization bands and drain metallization bands. Each source metallization band connects together a plurality, and optionally all the source tines of the second interconnect layer. Each drain metallization band connects together a plurality, and optionally all the drain tines of the second interconnect layer.

The bridging interconnect layer comprises a plurality of source bridging conductors and a plurality of drain bridging conductors. Each source bridging conductor connects together a plurality, and optionally all the source bands of the third interconnect layer. Each drain bridging conductor connects together a plurality, and optionally all the drain bands of the third interconnect layer. Source and drain bridging conductors are interleaved and substantially parallel. Each bridging conductor exhibits at least one undulation, optionally referred to as a “ripple”, that is perpendicular to the bridging layer. The ripples as a function of length along adjacent bridging conductors are substantially out of phase so that undulations along adjacent ribbons are staggered and displacements in a same direction resulting from the undulations are not adjacent.

The out of phase ripples operate to increase an average distance between adjacent bridging conductors and facilitate encapsulation of the bridging conductors with insulating material by reducing resistance to flow between the bridging conductors of an insulating material used to encapsulate the LFET switch. The reduction in flow resistance contributes to integrity of the insulation encapsulation. The increase in average distance contributes to increasing electrical resistance between bridging conductors and improving the ability of the LFET switch to prevent electrical breakdown.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE FIGURES

Non-limiting examples of embodiments of the invention are described below with reference to figures attached hereto that are listed following this paragraph. Identical structures, elements or parts that appear in more than one figure are generally labeled with a same numeral in all the figures in which they appear. Dimensions of components and features shown in the figures are chosen for convenience and clarity of presentation and are not necessarily shown to scale.

FIGS. 1-8 schematically illustrate configuration and fabrication of a LFET power switch, in accordance with an embodiment of the disclosure:

FIG. 1 schematically shows an optionally ceramic substrate having thereon a semiconductor substrate on which an LFET power switch is fabricated in accordance with an embodiment of the disclosure;

FIG. 2 schematically shows LFET transistors optionally divided into two sections formed on the semiconductor substrate shown in FIG. 1, in accordance with an embodiment of the disclosure;

FIG. 3 schematically shows a first interconnect layer having a metallization layer formed on the semiconductor substrate shown in FIG. 2 to electrically connect optionally all gates of the LFET transistors, in accordance with an embodiment of the disclosure;

FIG. 4 schematically shows a second interconnect layer of the power switch overlaying and separated from the first interconnect by an insulating layer (not shown), in accordance with an embodiment of the disclosure;

FIG. 5. schematically shows an insulation layer formed over the second interconnect layer and having source, drain, openings and gate openings, in accordance with an embodiment of the disclosure;

FIG. 6. schematically shows, a band interconnect layer comprising source and drain metallization bands, and gate lands, in accordance with an embodiment of the disclosure;

FIG. 7A schematically shows bridging conducting ribbons connecting the source and drain metallization bands shown in FIG. 6 to contact electrodes, in accordance with an embodiment of the disclosure;

FIG. 7B schematically shows wire bond bridging conductors connecting the source and drain metallization bands shown in FIG. 6 to contact electrodes, in accordance with an embodiment of the disclosure; and

FIG. 8 schematically shows the LFET power switch shown in FIGS. 1-7A completed and after encapsulation in an insulating encapsulation in accordance with an embodiment of the disclosure.

### DETAILED DESCRIPTION

In the discussion, unless otherwise stated, adjectives such as “substantially” and “about” modifying a condition or relationship characteristic of a feature or features of an embodiment of the disclosure, are understood to mean that the condition or characteristic is defined to within tolerances that are acceptable for operation of the embodiment in an application for which it is intended. Wherever a general term in the disclosure is illustrated by reference to an example instance or a list of example instances, the instance or instances referred to, are by way of non-limiting example instances of the general term, and the general term is not intended to be limited to the specific example instance or instances referred to. The phrase “in an embodiment”, whether or not associated with a permissive, such as “may”, “optionally”, or “by way of example”, is used to introduce for consideration an example, but not necessarily required, configuration of possible embodiments of the disclosure. Each of the verbs, “comprise” “include” and “have”, and conjugates thereof, are used to indicate that the object or objects of the verb are not necessarily a complete listing of components, elements or parts of the subject or subjects of the verb. Unless otherwise indicated explicitly or by context, the word “or” in the description and claims is considered to be the inclusive “or” rather than the exclusive or, and indicates at least one of, or any combination of more than one of items it conjoins.

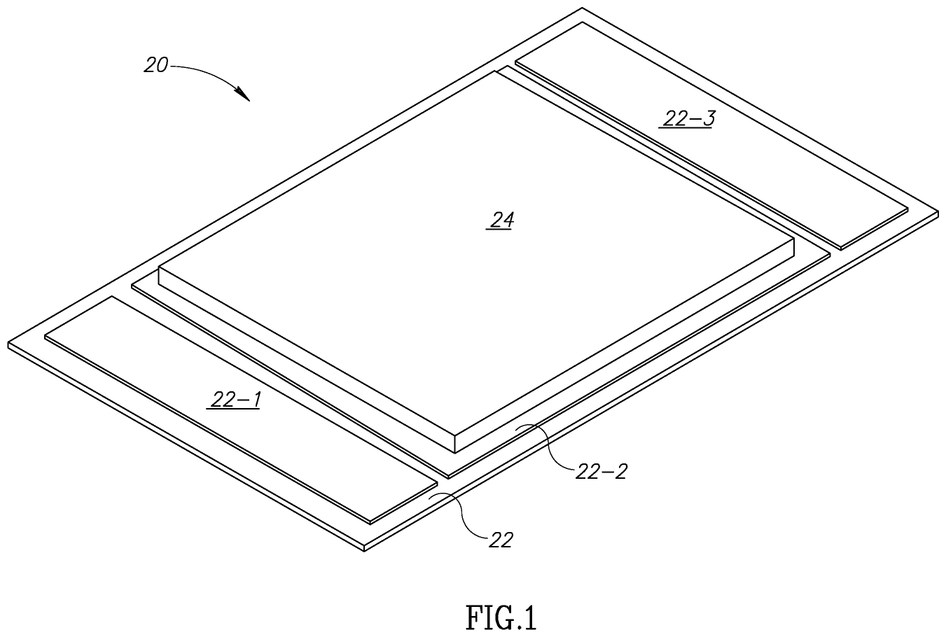

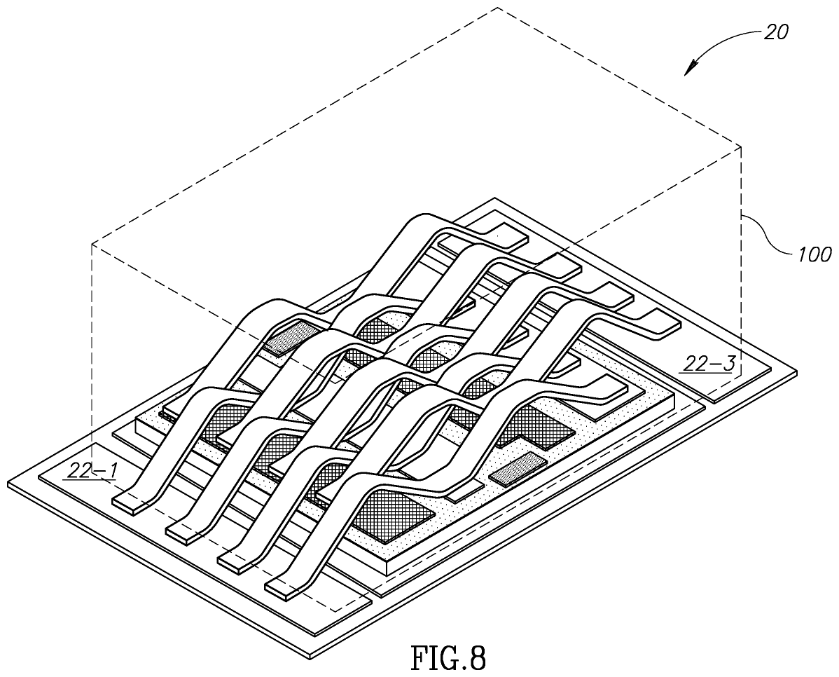

FIGS. 1-8 schematically illustrate configuration and fabrication of a LFET power switch 20, in accordance with an embodiment of the disclosure. The label 20 is used in each of FIGS. 1-7 to indicate that the LFET power switch, when shown at an incomplete stage of fabrication is a stage in the fabrication of LFET switch 20, shown completed in accordance with an embodiment of the disclosure in FIG. 8.

FIG. 1 schematically shows an optionally ceramic substrate 22 on which an LFET power switch 20 is fabricated in accordance with an embodiment of the disclosure. Ceramic substrate 22 has formed thereon a configuration of contact electrodes comprising a central electrode 22-2 on which a semiconductor substrate 24 is mounted and lateral electrodes 22-1 and 22-3. LFET transistors of power switch 20 are formed on semiconductor substrate 24 and lateral electrodes 22-1 and 22-2 are used to electrically couple the power switch to an external circuit. For convenience of presentation LFET transistors are assumed to be p-channel transistors so that charge carriers drift and current flows in a same through the transistors.

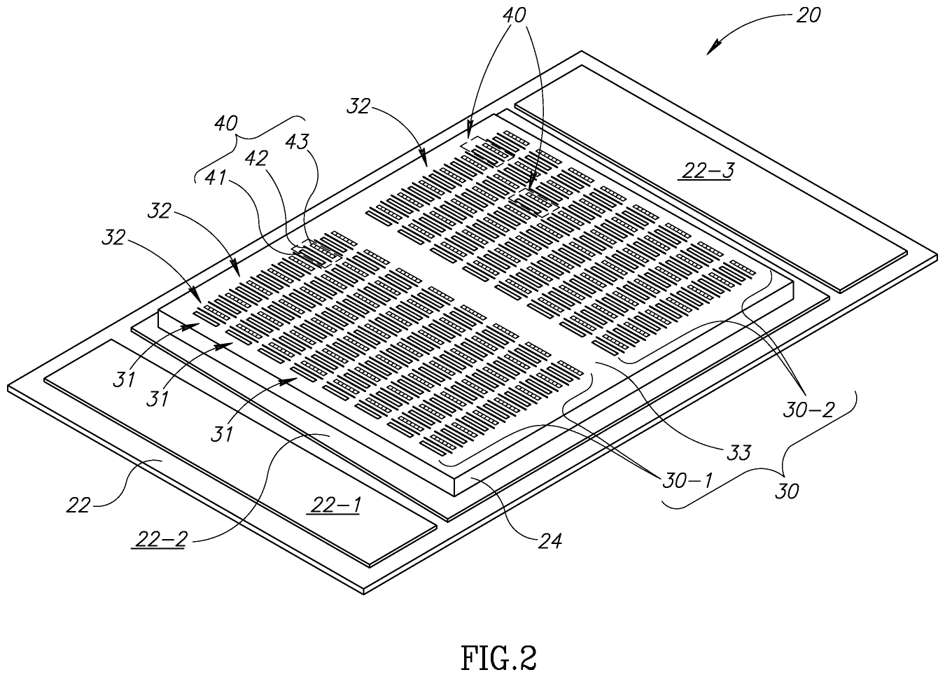

FIG. 2 schematically shows a divided array 30 of rows 31 and columns 32 of LFET transistors 40 optionally divided into two sections 30-1 and 30-2 by a divider strip 33 formed on semiconductor substrate 24. Some of the LFET transistors are surrounded by a dashed rectangle indicated by the label 40 to aid in visually identifying individual LFET transistors 40 and components of the LFET transistors. Each LFET transistor 40 comprises a source 41, a gate 42, and a drain 43. It is noted that in array 30 a same source 41 may function as a source for two adjacent transistors 40.

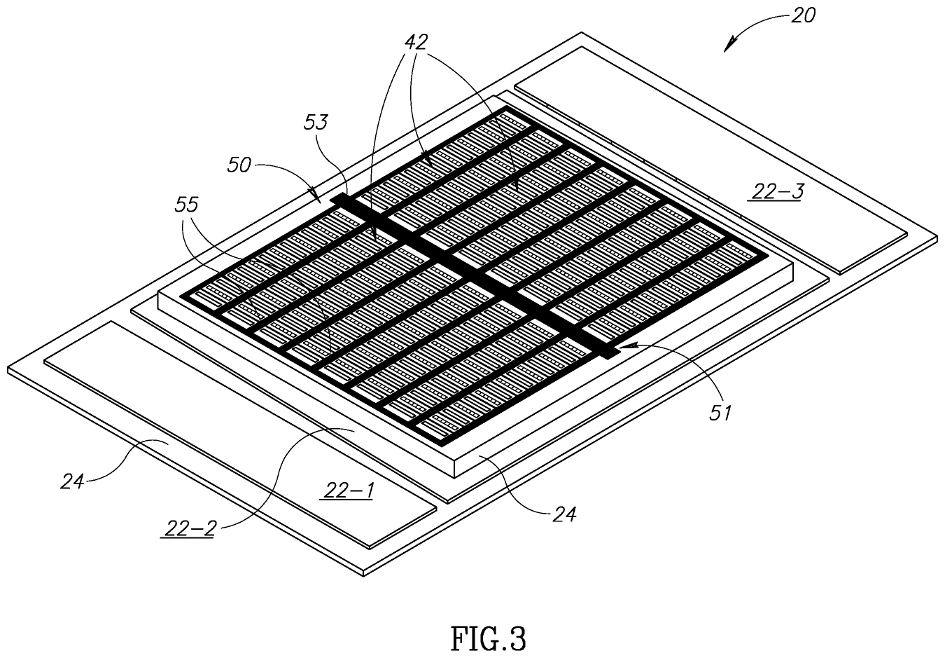

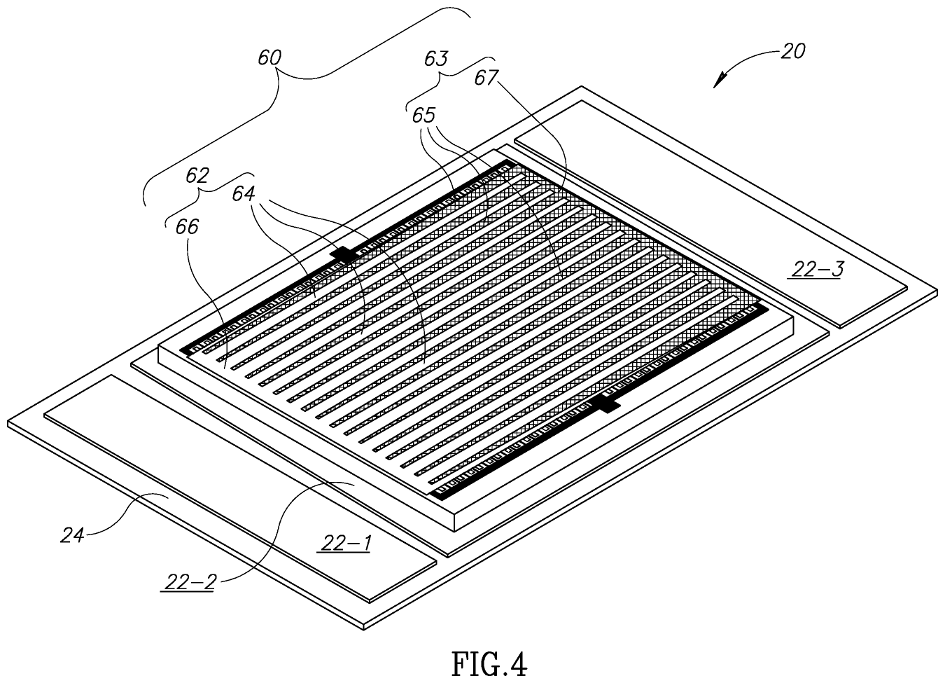

FIG. 3 schematically shows a first interconnect layer 50 having a metallization layer 51 formed on semiconductor substrate 24 to electrically connect optionally all gates 42 of LFET transistors 40. Metallization layer comprises a relatively wide central trunk 53 and a plurality of branches 55 extending from the trunk that connect to gates 42 of transistors 40. After forming, interconnect layer 50 and divided array 30 of transistors 40 are covered by an insulating layer (not shown) on which a second interconnect layer 60 schematically shown in FIG. 4 is formed, in accordance with an embodiment of the disclosure.

Interconnect layer 60 comprises a source metallization layer 62 and a drain metallization layer 63. Source metallization layer 62 comprises a plurality of optionally tapered source tines 64 that are optionally joined by a backbone 66. Each source tine 64 overlays optionally all transistors 40 in a same row 31 (FIG. 2) and is electrically coupled to sources 41 of optionally all the transistors in the row by conducting plugs (not shown) filling vias (not shown) formed in the insulation layer that communicate with interconnect layers 50 and 60. Drain metallization layer 63 comprises a plurality of optionally tapered drain tines 65 that are optionally joined by a backbone 67 and are interleaved with source tines 63. Each drain tine 65 overlays optionally all transistors 40 in a row 31 (FIG. 2) of the transistors and is electrically coupled to drains 43 of optionally all the transistors in the row by conducting plugs (not shown) formed in vias in the insulation layer between interconnect layers 50 and 60.

When transistors 40 are turned ON, each source tine 64 provides currents from current flowing in the source tine that enter sources 41 of optionally all transistors 40 in a row 31 (FIG. 2) underlying the source tine to flow through the transistors and exit the transistors via their respective drains 43. Each drain tine 65 receives the currents exiting drains 43 from optionally all transistors 40 in a row 31 underlying the drain tine. Source tines 64 optionally taper with distance from backbone 66 since a number of transistors to which a tine provides current may decrease with distance from backbone 66. As a result, magnitude of current flowing in a source tine 64 required to provide current to transistors 40 may decrease with distance from backbone 66. The tapering operates to facilitate uniform current density for current flowing along the source tine. Similarly, drain tines 65 advantageously taper with distance from backbone 67 since a number of transistors 40 from which a drain tine receives current via drains 43 may decrease with distance from the backbone. As a result, magnitude of current flowing in a drain tine 65 may decrease with distance from backbone 66. The tapering operates to support uniform current density for current flowing along the drain tine.

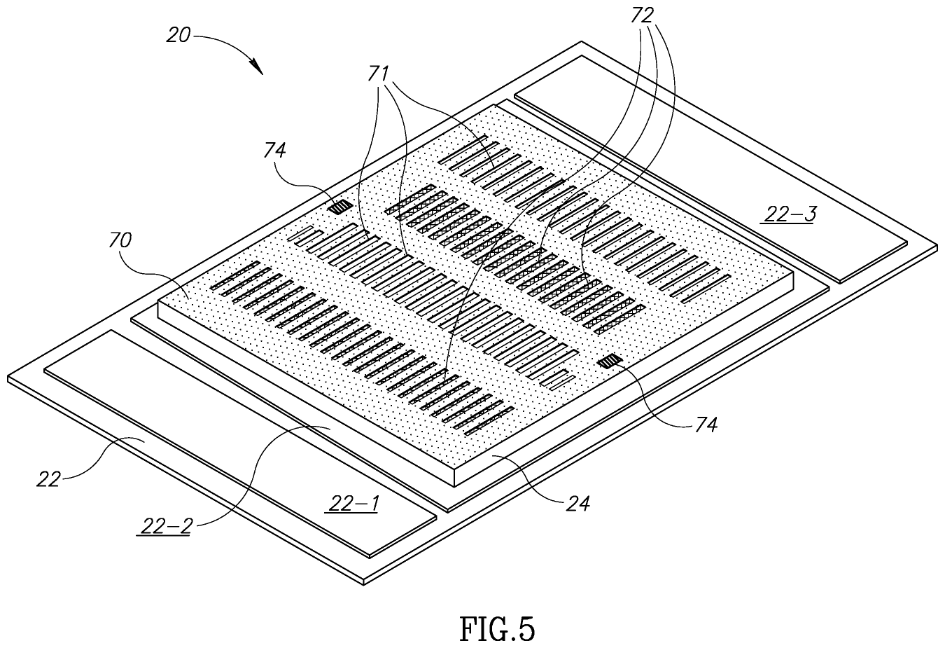

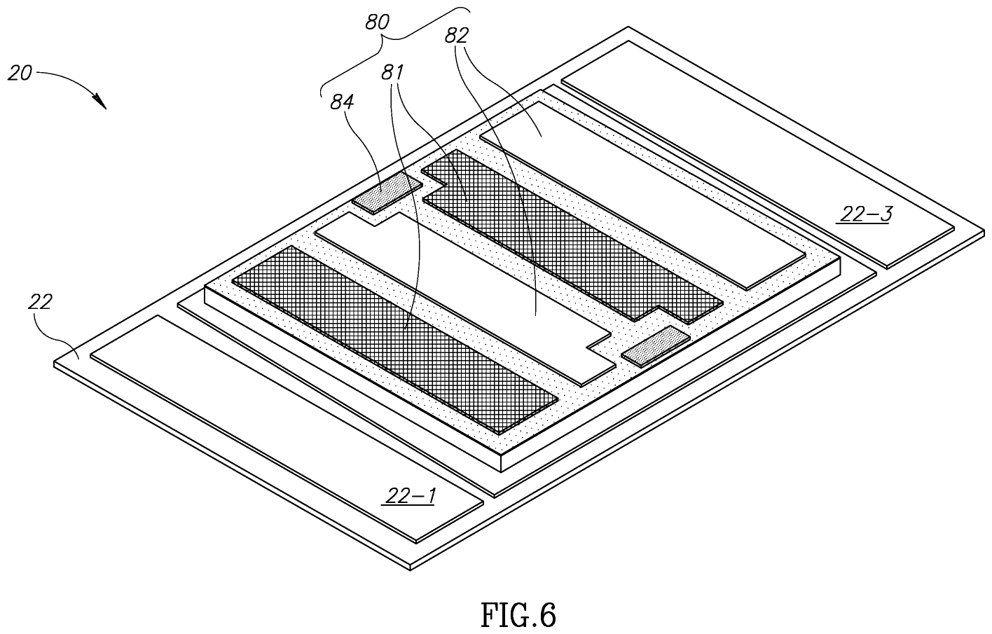

After interconnect layer 60 is formed, the layer is covered with an insulation layer 70 schematically indicated by stippling in FIG. 5. Insulation layer 70 is formed having source openings 71, drain openings 72 and gate opening 74. The openings fill with conductive fillings comprising the material from which conductive elements in an overlaying third, band interconnect layer 80 schematically shown in FIG. 6 are formed when the conductive elements are deposited on insulting layer 70. Band interconnect layer 80 optionally comprises source metallization bands 81, drain metallization bands 82, and gate lands 84. Source metallizations 81 are electrically connected to source tines 64 (FIG. 4) by the conductive fillings that fill source openings 71 (FIG. 5). In an embodiment source openings 71 formed closer to backbone 66 (FIG. 4) are larger than the source openings formed farther from the backbone so that the conductive fillings that fill the openings accommodate the tapering and current densities supported by of source tines 64. Drain metallization bands 82 are electrically connected to drain tines 65 by the conductive fillings that fill drain openings 72 (FIG. 5). In an embodiment drain openings 72 formed closer to backbone 67 (FIG. 4) are larger than the drain openings farther from the backbone so that the conductive fillings that fill the drain openings accommodate the tapering and current densities supported by drain tines 65. Gate lands 74 are electrically connected to gate metallization layer 50 by conductive filings that fill gate opening 74 (FIG. 5).

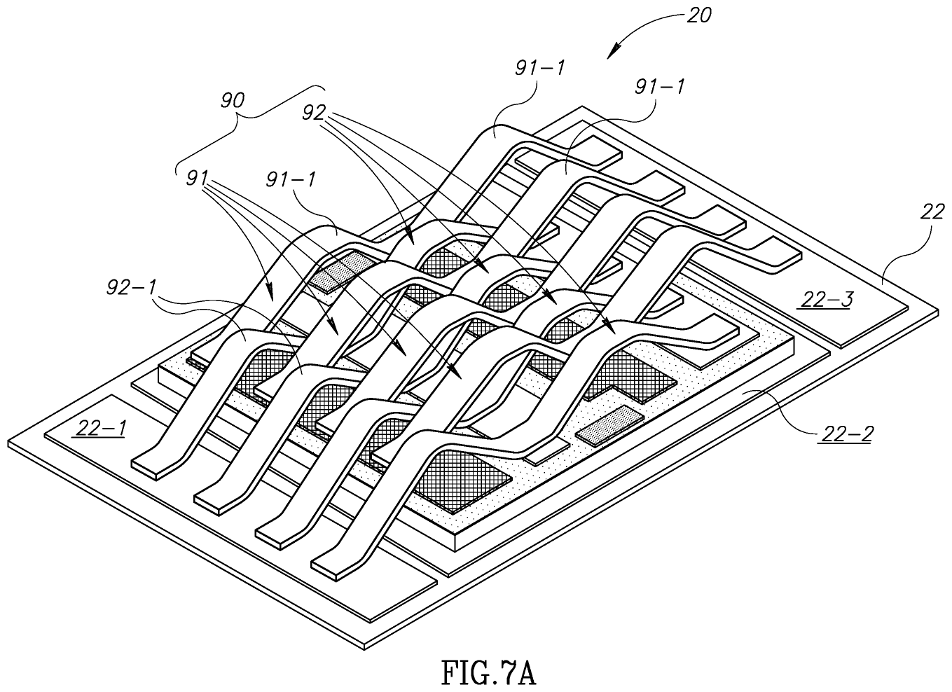

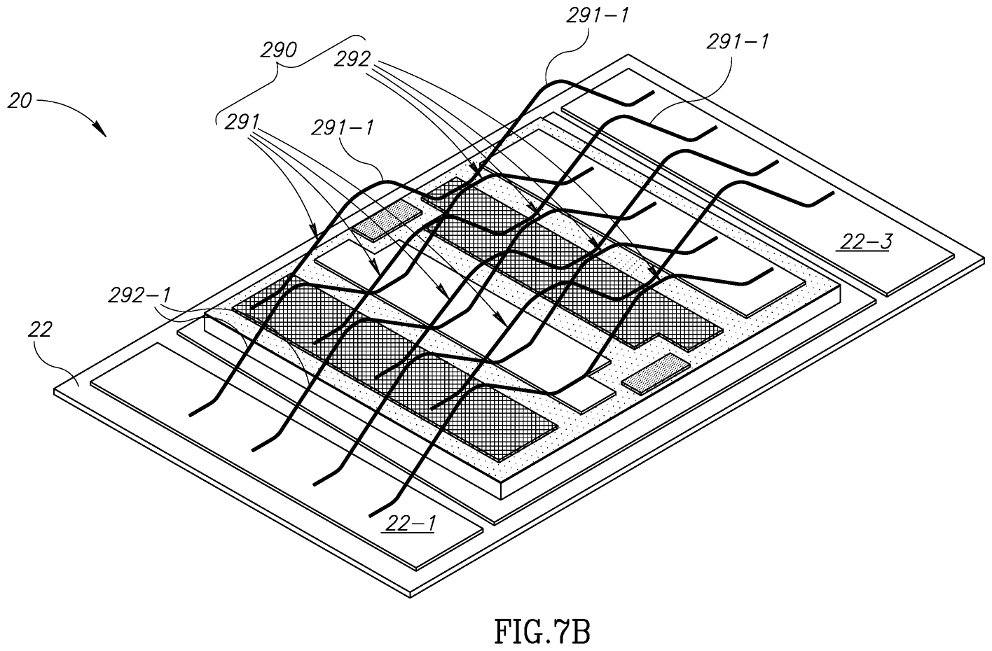

In an embodiment source and drain metallization bands 81 and 82 are electrically connected respectively to contact electrodes 22-1 and 22-3 by bridging conductors, optionally in the form of source and drain conducting ribbons 91 and 92 respectively, comprised in a bridging interconnect layer 90 schematically shown in FIG. 7A. Each source ribbon 91 electrically connects together, optionally all, source metallization bands 81 to contact electrode 22-1. Each drain ribbon 92 electrically connects together, optionally all, drain metallization bands 82 to contact electrode 22-2.

Source ribbons 91 and 92 are undulating ribbons characterized by ripples 91-1 and 92-1 respectively that provide displacements of regions of the ribbons perpendicular to a plane of interconnect layer 80 comprising metallization bands 81 and 82, in accordance with an embodiment of the disclosure. Ripples 91-1 are staggered relative to ripples 92-1 so that ripples 91-1 and 92-1 in adjacent ribbons 91 and 92 are not next to each other and are displaced relative to each other in a direction along which ribbons 91 and 92 extend. Optionally ripples 91-1 and 92-1 are substantially harmonic.

Ripples 91-1 and 92-1 and their relative displacements facilitate flow of a potting material used to encapsulate LFET power switch 20 in an insulating encapsulation and contribute to increase an average distance between adjacent metallization ribbons and thereby to integrity of the encapsulation and electrical resistance between the ribbons. An average distance between adjacent metallization ribbons 91 and 92 may have a value equal to an average distance between closest points along edges of the ribbons that face each other.

Whereas FIG. 7A schematically shows a bridging interconnect layer 90 comprising bridging conductors that are conducting ribbons 91 and 92, practice of an embodiment of the disclosure is not limited to bridging interconnect layers comprising conducting ribbons. A LFET power switch similar to power switch 20, in accordance with an embodiment of the disclosure may have a bridging interconnect layer comprising at least one bridging conductor that is an undulating conducting wire bond. FIG. 7B by way of example schematically shows a power switch 220 comprising a LFET power switch 220 having a bridging interconnect layer 290 comprising wire bond bridging conductors 291 and 292, in accordance with an embodiment of the disclosure.

FIG. 8 schematically shows LFET power switch 20 shown in FIGS. 1-7A completed in accordance with an embodiment after encapsulation in an insulating encapsulation 100 schematically shown in FIG. 8. The low resistance RDL LFET power switch may be connected as a component of an external circuit to function as a power switch by electrically coupling contact electrodes 22-1 and 22-2 to the circuit and connecting gate landings 84 to a controller that controls LFET switches 40 to turn ON and turn OFF. When transistors 40 are turned ON to turn power switch 20 ON, current optionally flows from contact electrode 22-1 to source ribbons 91 and therefrom through source metallization bands 81 and source tines 64 to pass through the transistors via sources 41 and exit the transistors via drains 43. Current exiting the transistors 40 flows to drain tines 65, through drain metallization bands 82 and therefrom though drain ribbons 92 to contact electrode 22-2.

By way of a numerical example, a LFET power switch similar to power switch 20 or 220 configured to switch ON and OFF currents having magnitude up to about 200 amperes at voltages up to about 1200 volts may comprise 3,000 LFET transistors and be fabricated on a substrate that is about 12.5 long by about 8 mm wide. Metallization layer 51 may have thickness equal to about 1 μm (micrometer). Source and drain tines 64 and 65 optionally taper from about 325 μm to about 110 μm, are separated by a gap having width equal to about 27 μm and have thickness equal to about 4.5 μm. Source and drain bands 81 and 82 may have thickness equal to about 4.5 μm and may be separated by gaps having width of about 500 μm. Ribbon bridging connectors are, by way of example, formed from Aluminum or Copper, and have thickness of about 100 μm and may be separated by a lateral space having width equal to about 500 μm. Simulations indicate that the RDL of the power switch has an on-resistance equal to about 5.5 mΩ (milliohms).

It is noted that whereas LFET power switch is described as comprising p-channel LFETs practice of embodiments of the disclosure are not limited to p-channel transistors or LFET transistors. For example, LFET transistors in a power switch in accordance with an embodiment may be n-channel and may be normally ON or normally OFF transistors. It is also noted that whereas tines 64 and 65 are described as tapered and connected to backbones in an embodiment the tines may not be tapered or may not be connected by backbones.

There is therefore provided in accordance with an embodiment of the disclosure, an electrical power switch, the power switch comprising: an array of rows and columns of transistors, each transistor having a source, drain, and gate; a plurality of internal interconnect layers comprising metallizations configured to connect the transistors to operate in parallel; a source electrode and a drain electrode for respectively connecting the sources and drains of the transistors to an external circuit; and a bridging interconnect layer comprising: a plurality of undulating source bridging conductors that provide electrical connections for the sources of the transistors to the source electrode; and a plurality of undulating drain bridging conductors that provide electrical connections for the drains of the transistors to the drain electrode. Optionally, each undulating bridging connectors comprises at least one ripple in which a region of the bridging connector is displaced perpendicular to a plane of the array of transistors. Optionally, the at least one ripple as a function of length along a source bridging conductor adjacent to a drain bridging conductor is out of phase with the at least one ripple as a function of length along the source bridging conductor. Alternatively or additionally, the at least one ripples has may have a harmonic-like shape.

In an embodiment, at least one of the bridging conductors has a ribbon shape. In an embodiment, at least one of the bridging conductors has a wire shape.

In an embodiment, the plurality of interconnect layers comprises a first interconnect layer comprising a metallization layer that connects together the gates of all the transistors in the array of transistors. Optionally, the plurality of interconnect layers comprises a second interconnect layer comprising a first, source metallization region that connects together a plurality of the sources of the transistors, and a second, drain metallization region that connects together a plurality of the drains of the transistors. Optionally, the source metallization region comprises a plurality of source tines each of which extends from a common source backbone and overlays a row of the transistors and electrically connects together the sources of a plurality of the transistors in the row. Additionally or alternatively, the drain metallization region comprises a plurality of drain tines each of which extends from a common drain backbone and overlays a row of the transistors and electrically connects together the drains of a plurality of the transistors in the row. Additionally or alternatively, the tines are tapered.

In an embodiment, the plurality of interconnect layers comprises a third, band interconnect layer comprising a plurality of source metallization bands interleaved with a plurality of drain metallization bands. Optionally, each of the source metallization bands electrically connects together a plurality of the source tines in the second interconnect layer. Additionally or alternatively, each of the drain metallization bands electrically connects together a plurality of the drain tines in the second interconnect layer. In an embodiment, each of the plurality of undulating source bridging conductors connects together a plurality of the source bands in the third interconnect layer. In an embodiment, each of the plurality of undulating drain bridging conductors connects together a plurality of the drain bands in the third interconnect layer.

In an embodiment, the transistors are lateral field effect (LFET) transistors.

Descriptions of embodiments of the invention in the present application are provided by way of example and are not intended to limit the scope of the invention. The described embodiments comprise different features, not all of which are required in all embodiments of the invention. Some embodiments utilize only some of the features or possible combinations of the features. Variations of embodiments of the invention that are described, and embodiments of the invention comprising different combinations of features noted in the described embodiments, will occur to persons of the art. The scope of the invention is limited only by the claims.

1. An electrical power switch, the power switch comprising:
an array of rows and columns of transistors, each transistor having a source, drain, and gate;
a plurality of internal interconnect layers comprising metallizations configured to connect the transistors to operate in parallel;
a source electrode and a drain electrode for respectively connecting the sources and drains of the transistors to an external circuit; and
a bridging interconnect layer comprising:
a plurality of undulating source bridging conductors that provide electrical connections for the sources of the transistors to the source electrode; and
a plurality of undulating drain bridging conductors that provide electrical connections for the drains of the transistors to the drain electrode.

2. The electrical power switch according to claim 1 wherein each undulating bridging connectors comprises at least one ripple in which a region of the bridging connector is displaced perpendicular to a plane of the array of transistors.

3. The electrical power switch according to claim 2 wherein the at least one ripple as a function of length along a source bridging conductor adjacent to a drain bridging conductor is out of phase with the at least one ripple as a function of length along the source bridging conductor.

4. The electrical power switch according to claim 2 wherein the at least one ripples has a harmonic-like shape.

5. The electrical power switch according to claim 1 wherein at least one of the bridging conductors has a ribbon shape.

6. The electrical power switch according to claim 1 wherein at least one of the bridging conductors has a wire shape.

7. The electrical power switch according to claim 1 wherein the plurality of interconnect layers comprises a first interconnect layer comprising a metallization layer that connects together the gates of all the transistors in the array of transistors.

8. The electrical power switch according to claim 7 wherein the plurality of interconnect layers comprises a second interconnect layer comprising a first, source metallization region that connects together a plurality of the sources of the transistors, and a second, drain metallization region that connects together a plurality of the drains of the transistors.

9. The electrical power switch according to claim 8 wherein the source metallization region comprises a plurality of source tines each of which extends from a common source backbone and overlays a row of the transistors and electrically connects together the sources of a plurality of the transistors in the row.

10. The electrical power switch according to claim 8 wherein the drain metallization region comprises a plurality of drain tines each of which extends from a common drain backbone and overlays a row of the transistors and electrically connects together the drains of a plurality of the transistors in the row.

11. The electrical power switch according to claim 9 wherein the tines are tapered.

12. The electrical power switch according to claim 8 wherein the plurality of interconnect layers comprising a third, band interconnect layer comprising a plurality of source metallization bands interleaved with a plurality of drain metallization bands.

13. The electrical power switch according to claim 12 wherein each of the source metallization bands electrically connects together a plurality of the source tines in the second interconnect layer.

14. The electrical power switch according to claim 12 wherein each of the drain metallization bands electrically connects together a plurality of the drain tines in the second interconnect layer.

15. The electrical power switch according to claim 12 wherein each of the plurality of undulating source bridging conductors connects together a plurality of the source bands in the third interconnect layer.

16. The electrical power switch according to claim 12 wherein each of the plurality of undulating drain bridging conductors connects together a plurality of the drain bands in the third interconnect layer.

17. The electrical power switch according to claim 1 wherein the transistors are lateral field effect (LFET) transistors.
